(19) United States
(12) Patent Application Publication
(10) Pub. No.: US 2012/0242359 A1
(43) Pub. Date: Sep. 27, 2012

(54) PROBE CARD DETECTING APPARATUS, WAFER POSITION ALIGNMENT APPARATUS AND WAFER POSITION ALIGNMENT METHOD

(75) Inventors: Hiroki OBI, Nirasaki City (JP); Hiroshi YAMADA, Nirasaki City (JP)

(73) Assignee: TOKYO ELECTRON LIMITED, Tokyo (JP)

(21) Appl. No.: 13/426,047

(22) Filed: Mar. 21, 2012

(30) Foreign Application Priority Data
Mar. 25, 2011 (JP) 2011-68989

(51) Int. Cl. G01R 31/00; G01R 31/20

(52) U.S. Cl. 324/750.16; 324/754.03

(57) ABSTRACT

A probe card detecting apparatus includes a probe detecting chamber having a supporting body, a probe card positioned and mounted detachably via a first holder on the predetermined position of the supporting body, a first imaging device movably provided in the probe detecting chamber to detect needle tips of at least two probes of the probe card, a probe correction card positioned and mounted detachably via a second holder to the predetermined position of the supporting body, and a control device. Under the control of the control device, using the first imaging device, a difference between a horizontal position of needle tips of at least two probes and a horizontal position of at least two targets is detected as a correction value for performing a position alignment of the at least two probes with the at least two electrode pads of said semiconductor wafer.

### CROSS-REFERENCE TO RELATED APPLICATION

This application claims the benefit of Japanese Patent Application No. 2011-68989, filed on Mar. 25, 2011, in the Japan Patent Office, the disclosure of which is incorporated herein in its entirety by reference.

### TECHNICAL FIELD

The present disclosure relates to a probe card detecting apparatus, a wafer position alignment apparatus and a wafer position alignment method that are applicable to a wafer inspection apparatus for inspecting electrical characteristics of a semiconductor wafer, and more particularly, to a probe card detecting apparatus, a wafer position alignment apparatus and a wafer position alignment method for performing quick alignment of a probe card with a semiconductor wafer in a wafer inspection apparatus.

### BACKGROUND

For a wafer inspection apparatus, there is, for example, a probe apparatus which inspects electrical characteristics of multiple devices with a semiconductor wafer being intact.

Typically, the wafer inspection apparatus is configured to include a loader chamber for transferring a semiconductor wafer and an inspection chamber for inspecting electrical characteristics of a semiconductor wafer. The wafer inspection apparatus is configured to control various devices in the loader chamber and the inspection chamber using a control device and configured to inspect electrical characteristics of a semiconductor wafer. The loader chamber includes a cassette mounting portion for mounting semiconductor wafers using the cassette, a wafer transfer mechanism for transferring the semiconductor wafer between the cassette and the inspection chamber, and a pre-alignment mechanism for performing a preliminary position alignment (pre-alignment) of the semiconductor wafer while the wafer transfer mechanism is transferring the semiconductor wafer. The inspection chamber includes a mounting base which moves in the direction of X, Y, Z and θ while being loaded with the semiconductor wafer from the loader chamber, a probe card placed on the mounting base, and an alignment mechanism for performing a position alignment of a plurality of probes of the probe card with a plurality of electrodes of the semiconductor wafer, in cooperation with the mounting base. The inspection chamber is configured to inspect electrical characteristics of a plurality of devices formed on the semiconductor wafer, after performing the alignment of the semiconductor wafer with the probe card.

In the alignment of the semiconductor wafer with the probe card, as described above, an upper camera and a lower camera are provided in such a manner that the needle tip of the probe can be detected with the lower camera and the electrode pad of the semiconductor wafer can be detected with the upper camera. Specifically, the lower camera provided in the mounting base is used to detect needle tips of a plurality of probes of the probe card to obtain their XY coordinates and, at the same time, the upper camera provided in the alignment mechanism is used to detect a plurality of electrode pads of the semiconductor wafer on the mounting base to obtain their XY coordinates. The alignment of the needle tip of the probe with the electrode pad is performed based on the XY coordinates of the needle tip of the probe and the electrode pad detected by the upper and the lower cameras. In another alignment method, the alignment is performed by placing a dummy wafer on the mounting base, contacting the dummy wafer with a plurality of probes of the probe card to add traces of probe needles on the dummy wafer, and, based on the traces of probe needles, detecting indirectly the needle tip of the probe.

However, when performing the alignment of a probe card with a semiconductor wafer, a camera is required for detecting the needle tip of the probe in the inspection chamber of the wafer inspection apparatus. Also, it becomes increasingly difficult to detect the needle tip, since the number of probes increases dramatically with high-density integration devices. Further, in the method of using a dummy wafer to collect traces of the probe, a dummy wafer is placed on a mounding base in an inspection chamber for each probe card, and after detecting traces of probe needles, the dummy wafer has to be removed from the mounting base, which requires a significant amount of time for collecting traces of the needle.

### SUMMARY

The present disclosure provides a probe card detecting apparatus, a wafer position alignment apparatus and a wafer position alignment method through which an alignment of a semiconductor wafer with a probe card can be performed quickly and reliably, without needing to detect the needle tip of the probe of the probe card in the inspection chamber of the wafer inspection apparatus and without using the dummy wafer.

According to a first embodiment of the present disclosure, a probe card detecting apparatus includes a probe detecting chamber having a supporting body on which a probe card is mounted detachably at a predetermined position, a probe card positioned and mounted detachably via a first holder on the predetermined position of the supporting body, a first imaging device provided movably in the probe detecting chamber to detect needle tips of at least two probes of the probe card; a probe correction card that, instead of the probe card, is positioned and mounted detachably via a second holder in the predetermined position of the supporting body and has at least two targets corresponding to the at least two probes, and a control device. In this embodiment, under the control of the control device, using the first imaging device in the probe detecting chamber, a difference between a horizontal position of needle tips of the at least two probes detected by the first imaging device in the probe inspection chamber and a horizontal position of the at least two targets is detected as a correction value used for performing a position alignment of the at least two probes of the probe card in the inspection chamber and the at least two electrode pads of the semiconductor wafer.

According to another embodiment of the present disclosure, a wafer position alignment apparatus includes a position alignment chamber; a moving body movably provided in the position alignment chamber; a second imaging device provided on the moving body, and a control device. In this embodiment, under the control of the control device, the moving body which mounts thereon a second holder together with a probe correction card for which the correction value is obtained in a probe card detecting apparatus is moved to detect at least two targets of the probe correction card using the second imaging device. Further, in this embodiment, the moving body which mounts thereon a semiconductor wafer is moved to detect at least two electrode pads of the semiconductor wafer and, at the same time, the moving body is moved horizontally by the correction value from the position at which the electrode pad is detected.

According to another embodiment of the present disclosure, a wafer position alignment method includes finding a correction value needed for a position alignment of a semiconductor wafer with a probe card mounted in a probe detecting chamber with the use of a first imaging device in a probe card detecting apparatus, using at least two probes of the probe card positioned and mounted detachably via a first holder in the probe detecting chamber and using at least two targets of the probe correction card positioned and mounted detachably via a second holder in the probe detecting chamber; moving the probe correction card held by the second holder via a moving body in a wafer position alignment apparatus to detect the at least two targets using a second imaging device; moving the semiconductor wafer via the moving body in the wafer position alignment apparatus to detect at least two electrode pads of the semiconductor wafer using the second imaging device; and moving the semiconductor wafer via the moving body in accordance with the correction value to perform a position alignment with the probe card mounted in the inspection chamber.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing an embodiment of a wafer inspection apparatus employing a wafer position alignment apparatus.

FIGS. 2A and 2B are diagrams showing the wafer inspection apparatus shown in FIG. 1, respectively, where FIG. 2A is a perspective view from the front side of the apparatus and FIG. 2B is a perspective view from the rear side of the apparatus.

FIGS. 3A and 3B are diagrams showing a main portion of an alignment chamber of the wafer inspection apparatus, where FIG. 3A is a side view of the main portion of the alignment chamber and FIG. 3B is a top view of the main portion of the alignment chamber.

FIG. 4 is side view showing a main portion of an inspection chamber of the wafer inspection apparatus.

FIGS. 5A and 5B are schematic diagrams showing the principle of the probe card detecting apparatus, where FIG. 5A shows a step of detecting the needle tip of the probe of the probe card mounted in a probe detecting chamber and FIG. 5B shows a step of detecting the target of a probe correction card mounted in the probe detecting chamber, respectively.

FIGS. 6A, 6B and 6C are schematic diagrams showing the principle of the alignment performed in an alignment chamber of the wafer inspection apparatus, where FIG. 6A shows a step of detecting the target of the probe correction card, FIG. 6B shows a step of detecting the electrode pad of the semiconductor wafer, and FIG. 6C shows a step of performing the alignment of the semiconductor wafer, respectively.

FIG. 7 is a schematic diagram showing the principle of inspecting in the inspecting chamber the semiconductor wafer aligned in the alignment chamber.

### DETAILED DESCRIPTION

Embodiments of the present disclosure will now be described in detail with reference to the drawings.

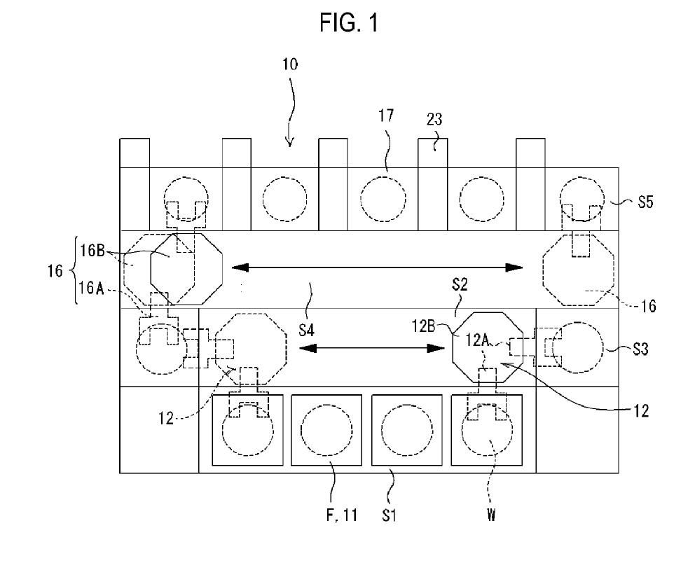

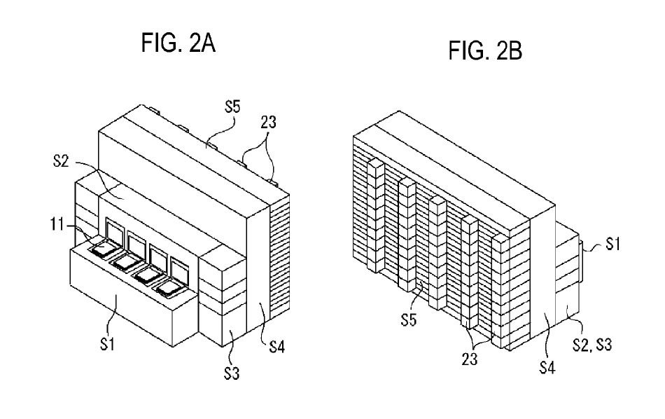

The following is a description of a wafer inspection apparatus to which embodiments of the present disclosure may be applied. The wafer inspection apparatus, for example, as shown in FIG. 1, FIG. 2A and FIG. 2B, is partitioned into an elongated loading/unloading region S1 arranged to load/unload semiconductor wafers contained in a cassette, a first transferring region S2 formed to transfer the semiconductor wafers along the loading/unloading region S1, an alignment region S3 formed on both ends of the first transferring region S2, a second transferring region S4 formed to transfer the semiconductor wafers along the first transferring region S2 and a semiconductor wafer inspection region S5 formed along the second transferring region S4. The wafer inspection apparatus is accommodated in a housing, as shown in FIGS. 2A and 2B. Each of these regions S1 to S5 is formed as an independent space. In each of these regions S1 to S5, a dedicated equipment is provided which is controlled by a controller.

In the loading/unloading region S1, as shown in FIG. 1, FIG. 2A and FIG. 2B, four mounting mechanisms 11 for mounting a housing F, such as FOUP (Front Open Unified Pod) accommodating a plurality of semiconductor wafers are provided. These mounting mechanisms 11 are configured to mount and hold the housing F that has been transferred by an automatic transferring device, etc. In the first transferring region S2 adjacent to the loading/unloading region S1, a first wafer transferring mechanism 12 for transferring a semiconductor wafer W in each housing F mounted on each mounting mechanism 11 is provided. The first wafer transferring mechanism 12 is configured to transfer the semiconductor wafer W in the first transferring region S2. The first wafer transferring mechanism 12 includes an arm 12A configured to vacuum-attract the semiconductor wafer W or elevate vertically while revolving horizontally to support the below-described wafer holder, a body 12B having a built-in driving mechanism that allows the arm 12A to revolve and elevate, and a moving mechanism that moves the body 12B. The first wafer transferring mechanism 12 is configured to move in the first transferring region S2 via the moving mechanism, thus transferring the semiconductor wafer W.

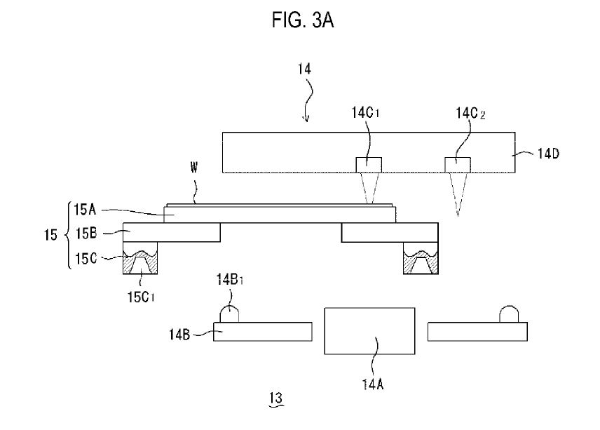

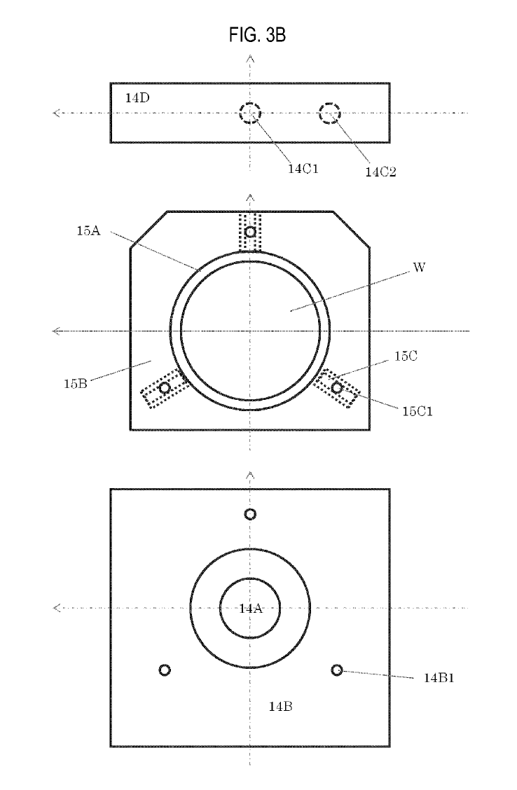

As shown in FIG. 1, FIG. 2A and FIG. 2B, the alignment region S3 formed on both ends of the first transferring region S2 is provided with a pre-alignment chamber for the semiconductor wafer W, an alignment chamber 13 for the semiconductor wafer W and a buffer chamber. The pre-alignment chamber, the alignment chamber 13 and the buffer chamber are arranged vertically one above another. The pre-alignment chamber is provided with a pre-alignment mechanism that pre-aligns the semiconductor wafer W, and the alignment chamber 13 is provided with an alignment mechanism 14 (see FIGS. 3A and 3B) that aligns the semiconductor wafer W. Further, the buffer chamber is provided with an accommodating mechanism that accommodates the semiconductor wafer W. The buffer chamber is used as storage for temporarily holding the semiconductor wafers W after the completion of inspection, or as storage for accommodating wafers for polishing needles.

Thus, a wafer position alignment apparatus according to one embodiment of the present disclosure (hereinafter referred to as “alignment apparatus”) includes an alignment chamber 13 and an alignment mechanism 14 provided in the alignment chamber 13. The alignment mechanism 14, as shown in FIGS. 3A and 3B, includes a tubular moving body 14A configured to move vertically and horizontally while being provided on a bottom surface, an annular positioning member 14B for positioning a wafer holder 15 in a predetermined direction in a state of being fixed on the bottom surface while surrounding the moving body 14A, a first/second camera 14C₁ and 14C₂ for aligning the semiconductor wafer W on the wafer holder 15 in cooperation with the moving body 14A, and a bridge 14D on which the first and second cameras 14C₁ and 14C₂ are fixed. Further, the first and second cameras 14C₁ and 14C₂ are configured to capture, at their respective focal positions (alignment heights), an image of the upper surface of the semiconductor wafer W.

The positioning member 14B is formed as an annular plate member having an inner diameter larger than an outer diameter of the moving body 14A, as shown in FIGS. 3A and 3B. On the upper surface of the positioning member 14B, a plurality of (e.g., three) of protrusions 14B₁ are formed at predetermined intervals in the circumferential direction. The plurality of protrusions 14B₁ are arranged on a circle whose center is vertically aligned with the first camera 14C₁. XY coordinates of each protrusion (when it is viewed from the upper surface of the positioning member 14B) is predetermined to indicate a position equidistant from the origin of the XY coordinates. Further, in the alignment chamber, XY coordinates of needle tips of a plurality of probes of a probe card are preset, which will be explained below.

In addition, the wafer holder 15 includes a holding plate 15A configured to hold the semiconductor wafer W, an annular supporting body 15B configured to support detachably the holding plate 15A, and a plurality of positioning portions 15C that are formed on the bottom surface of the supporting body 15B and have recesses 15C₁ respectively fitted with the plurality of protrusions 14B₁ of the positioning member 14B. Further, the wafer holder 15 is supported substantially in the horizontal direction by the positioning member 14B so as to be placed in a constant position. In addition, as shown in FIGS. 3A and 3B, a through-hole whose diameter is larger than the moving body 14A is formed in the supporting body 15B so that the moving body 14A may pass through the through-hole and move in the XY direction within the through-hole.

Beneath the center portion of the wafer holder 15 supported by the positioning member 14B is provided the moving body 14A. The moving body 14A is configured to rise vertically from just beneath the wafer holder 15 such that it makes contact with the holding plate 15A and passes through the through-hole of the supporting body 15B, lifting up the holding plate 15A from the supporting body 15B to the alignment height. Further, the moving body 14A is configured to move in the XY direction within the through-hole of the supporting body 15B at the alignment height and cooperate with the first and second cameras 14C₁ and 14C₂ to align the semiconductor wafer W. Further, while returning to its original position after alignment, the moving body 14A returns, on the supporting body 15B, the holding plate 15A holding the semiconductor wafer after alignment. The semiconductor wafer W after alignment is transferred by the wafer holder 15 to the inspection region S5, as will be described below.

The alignment mechanism 14 is used after obtaining a correction value of the probe for performing the alignment of the semiconductor wafer with the probe card used in the inspection chamber 17 of the probe card detecting apparatus, which will be described later.

In addition, as shown in FIG. 1, FIGS. 2A and 2B, a second wafer transferring mechanism 16 is provided in the second transferring region S4 adjacent to the first transferring region S2 and the alignment region S3. The second wafer transferring mechanism 16 is configured to move within the second transferring region S4 and transfers the semiconductor wafer W via the wafer holder 15 between the alignment region S3 and the inspection region S5. Similar to the configuration of the first wafer transferring mechanism 13, the second wafer transferring mechanism 16 includes an arm 16A, a body 16B and a moving mechanism.

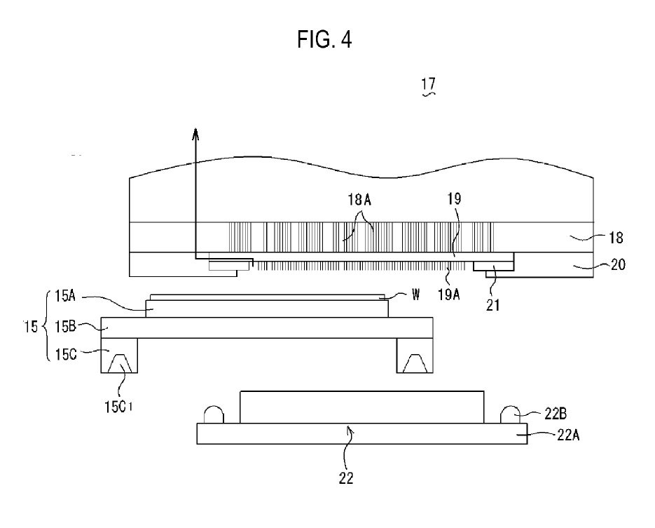

As shown in FIG. 1, in the inspection region S5 adjacent to the second transferring region S4, a plurality of inspection chambers 17 are arranged (at five locations in this embodiment) along the region S5 at predetermined intervals. Such inspection chambers 17 are configured to, after alignment, inspect the electrical characteristics of the semiconductor wafer W which is transferred via the wafer holder 15 by the second wafer transferring mechanism 16. In addition, the inspection chamber 17, as shown in FIGS. 2A and 2B, is formed as a laminate structure that is multi-layered vertically at each arrangement location of the inspection region S5. Any inspection chamber 17 in each layer has the same structure. Therefore, one inspection chamber 17 will be exemplified, for example by referring to FIG. 4.

As shown in FIG. 4, the inspection chamber 17, includes a probe card 19 that has a plurality of probes 19A corresponding to a plurality of electrodes of the semiconductor wafer W and that is fixed to a head plate 18 and a plurality of blocks of pogo pins 18A for connecting the probe card 19 to a tester. The inspection chamber 17 further includes a seal member for wafer absorption (hereinafter simply referred to as “seal member”) 21 formed in a ring shape of a predetermined width to surround the plurality of probes 19A with its outer peripheral portion fixed via a fixed ring 20 having an annular shape which is attached to the underside of the outer peripheral portion of the head plate 18 and an elevation body 22 lifting up the wafer holder 15 in an integrated fashion. The inspection chamber 17 further includes an exhaust means (for example, vacuum pump) for creating a vacuum in the sealed space formed between the probe card 19 and the semiconductor wafer W which elastically makes contact with the seal member 21 through the elevation body 22 such that the plurality of electrodes of semiconductor wafer W makes contact with the plurality of probes 19A as a whole. The periphery of the probe card 19, the fixed ring 20 and the head plate 18 have, respectively, an exhaust passage for exhausting in the direction indicated by the arrow in FIG. 4. The outlet of the exhaust passage is connected to a vacuum pump through a pipe.

As shown in FIG. 4, a flange portion 22A is formed on the lower surface of the elevation body 22. Further, on the upper surface of the flange portion 22A, a plurality of protrusions 22B, which can fit into the recesses 15C₁ of the positioning member 15C of the wafer holder 15, are formed at predetermined intervals in the circumferential direction. These protrusions 22B are disposed at positions having XY coordinates, which are the same as those corresponding to the plurality of protrusions 14B₁ formed in the positioning member 14 within the alignment chamber 13. In other words, the mirror images of the XY coordinates in the inspection chamber 17 are aligned with the XY coordinates in the alignment chamber 13. Thus, the semiconductor wafer W aligned in the alignment chamber 13 is transferred via the holding plate 15A such that the plurality of electrodes makes contact with the plurality of probes 19A of the probe card 19 reliably. In addition, the flange portion 22A and the plurality of protrusions 22B of the elevation body 22 correspond to the positioning member 14B in the alignment chamber 13.

The elevation body 22 lifts up the wafer holder 15 supported on the plurality of protrusions 22B of the flange 22A toward the probe card 19 so that the periphery of the semiconductor wafer W may be in contact with the seal member 21 so as to create a sealed space. The vacuum pump may vacuum-attract the sealed space, vacuum-attracting the semiconductor wafer W against the seal member 21. Further, the elevation body 22 is driven to leave the semiconductor wafer W after vacuum-attracting on the probe card 19 and move downward, thus separating the wafer holder 15 from the semiconductor wafer W. Thereafter, the elevation body 22 is driven to be elevated so that the semiconductor wafer W may be in contact with the plurality of probes under pressure. After inspection, the inspected semiconductor wafer W is unloaded from the inspection chamber 17 by following the reverse path.

Thus, in this embodiment, the space of the inspection chamber 17 can be secured sufficiently as long as there is space for loading/unloading the wafer holder 15 and space for the elevation body 22 to elevate so that the semiconductor wafer W which is held by the wafer holder 15 may make contact with the probe card 19. Therefore, the inspection chamber 17 may be reduced significantly in height, compared with the conventional inspection chamber, and employ the layered structure as described above to reduce the installation space of the inspection chamber significantly. In addition, the elevation body 22 does not need to move in the XY direction, thus also reducing the space occupied by the inspection chamber 17 significantly. Further, since the alignment mechanism 14 may be shared by each inspection chamber 17, there is no need to provide the expensive alignment mechanism 14 for every inspection chamber 17 as conventionally provided, thus achieving significant cost savings.

In addition, as shown in FIG. 1, FIGS. 2A and 2B, in each inspection chamber 17, is provided a cooling duct 23, respectively, and each cooling device (not shown) cools down the semiconductor wafer W which generates heat during inspection so that the semiconductor may maintain a constant temperature.

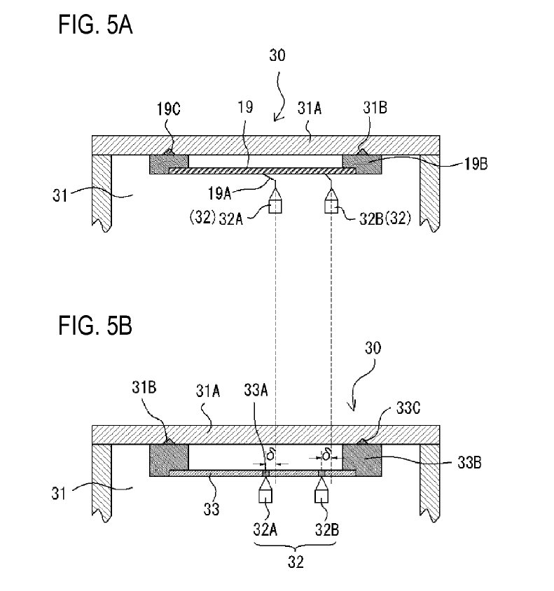

Next, an embodiment of the present disclosure, which is applied to the wafer inspection apparatus 10, will be described with reference to FIG. 5A to FIG. 7. In addition, in the following description, the components which are the same as or correspond to the components of the wafer inspection apparatus 10 are described using the same reference numerals.

The probe card detecting apparatus 30 of this embodiment, as shown in FIGS. 5A and 5B, includes a probe detecting chamber 31 for detecting the needle tip of the probe card 19, a supporting body 31A formed on the upper surface of the probe detecting chamber 31, a first imaging device 32 movably provided within the probe detecting chamber 31, and a clamping mechanism for fixing the probe card 19 or a probe correction card 33, detachably mounted in the center of the supporting body 31A, to the supporting body 31A. Further, the probe card detecting apparatus 30 is configured to obtain indirectly, through the probe correction card 33, a horizontal position of the needle tip of the probe card 19, the horizontal position being needed for alignment in the alignment chamber 13 of the wafer inspection apparatus 10. The probe card 19 is used in the inspection chamber 17 of the wafer inspection apparatus 10 and includes a dedicated probe correction card 33. In other words, each probe correction card 33 is prepared and provided individually depending on the type of probe card 19, such as cantilever type, MEMS type, vertical type and so on.

Thus, the supporting body 31A is formed with the coordinate axis aligned with the coordinate axis of the head plate 19 in the inspection chamber 17, and the XY coordinates of the needle tip of the probe 19A of the probe card 19 detected in the probe detecting chamber 31 are arranged to match the XY coordinates of the needle tip of the probe 19A of the probe card 19 mounted on the head plate 18 in the inspection chamber 17.

In the probe card 19, as schematically shown in FIGS. 5A and 5B, a first holder (hereinafter referred to as a first card holder) 19B is provided, and the probe card 19 is detachably mounted in the center of the supporting body 31A via the first card holder 19B. On the upper surface of the first card holder 19B, three positioning protrusions 19C are formed, respective protrusions 19C being disposed at predetermined intervals. In addition, on the supporting body 31A, three positioning recesses 31B corresponding to the positioning protrusions 19C of the probe card 19 are formed. The recess 31B is formed as an elongated hole which is elongated in the radial direction of the probe card 19, and the inner circumferential surface of the elongated hole is formed as a tapered surface (i.e., the elongated hole shrinks as it goes upward from the bottom surface of the supporting body 31A). In other words, protrusions 19C and recesses 31B make up a positioning mechanism for positioning the probe card 19, and the probe card 19 may be accurately positioned and fitted into a predetermined location in the supporting body 31A without being shaky by fitting protrusions 19C into recesses 31B. A positioning mechanism may be used which was proposed in the specification of Japanese Patent Application Publication No. 2011-045338.

The first imaging device 32, as shown in FIGS. 5A and 5B, includes a first camera 32A, a second camera 32B, and a moving mechanism configured to move while supporting the first and second cameras 32A and 32B. Further, the first imaging device 32 is configured to detect two probes 19A of a plurality of probes 19A of the probe card 19 and two targets 33A of a probe correction card 33 from below respectively through the first and second cameras 32A and 32B moving via the moving mechanism. The first camera 32A and the second camera 32B are configured to adjust the space therebetween as needed. Further, depending on the configuration of the moving mechanism, the first and second cameras 32A and 32B may also be replaced with a single camera.

The two probes 19 are in contact with the electrode pad in the center of the semiconductor wafer and the electrode pad in the periphery of the semiconductor wafer during inspection. In other words, the dimension between two probes 19A is the same as that between two electrode pads. The electrode pad in the center of the semiconductor wafer and the electrode pad in the periphery of the semiconductor wafer are arranged with a predetermined space between them on the same axis on the semiconductor wafer. In addition, two targets 33A corresponding to the two electrode pads are formed in the probe correction card 33. Further, in this embodiment, as shown in FIG. 5B, when the probe correction card 33 is in a state of being mounted on the supporting body 31A, the two targets 33A are misaligned by a predetermined dimension δ in the horizontal direction from the center of the two probes 19A of the probe card 19. The dimension δ (the difference between the horizontal positions of the probe 19A and the target 33A) becomes a correction value for the horizontal position of the needle tip of the probe 19A of the probe card 19 within the inspection chamber 17 in the alignment chamber 13, as described later.

In addition, as shown in FIG. 5B, a second probe card holder (hereinafter, a second card holder) 33B is provided to the probe correction card 33, and the probe correction card 33 is detachably mounted in the center of the supporting body 31A via the second card holder 33B. Further, in the second card holder 33B, as in the case with the first card holder 19B, three protrusions 33C are spaced from each other at predetermined intervals, so that three protrusions 33C and recesses 31B of the supporting body 31A make up a positioning mechanism.

Next, a wafer position alignment method in this embodiment is described. In this embodiment, the probe card detecting apparatus 30 and the alignment apparatus of the wafer inspection apparatus 10 are used. First of all, as shown in FIG. 5A, after the probe card 19 is positioned and mounted on the supporting body 31A via the positioning mechanism in the probe detecting chamber 31 of the probe card detecting apparatus 30, the probe card 19 is fixed to the supporting body 31A by a clamp mechanism. In this state, if the first and second cameras 32A and 32B move via the moving mechanism and needle tips of two probes 19A of the probe card 19 are detected from below, the XY coordinates of the horizontal position of each needle tip is stored (or registered) in a storage unit of the control device. Once the needle tips of the probe 19A are registered with the control device, the probe card 19 is removed from the supporting body 31A.

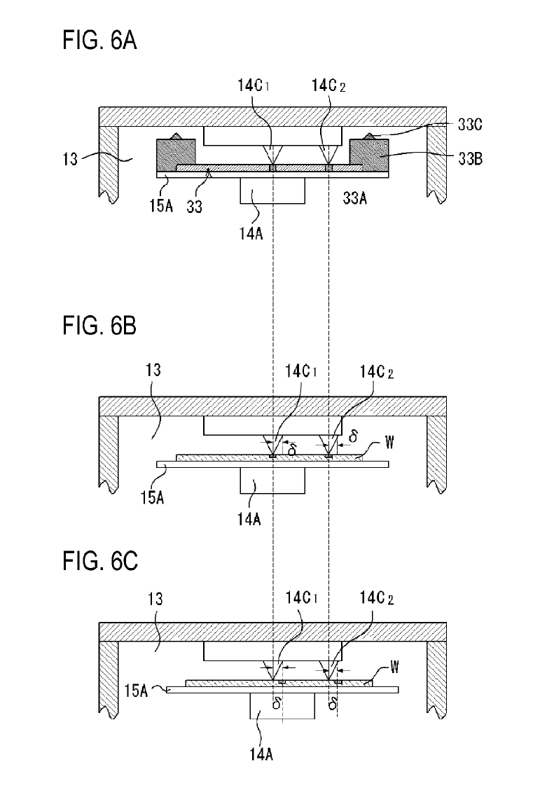

Next, as shown in FIG. 5B, the probe correction card 33, instead of the probe card 19, is positioned and mounted on a predetermined location in the supporting body 31A (the location being the same as that of the probe card 19) via the positioning mechanism, and fixed on the supporting body 31A via the clamp mechanism. In addition, the first and second cameras 32A and 32B are moved via the moving mechanism and two targets 33A of the probe correction card 33 are detected from below, the XY coordinates of the horizontal position of each target is registered in a storage unit of the control device. Further, in the control device, a difference between the XY coordinates of the needle tip of the probe 19A and the XY coordinates of target 33A is obtained as a correction value for the horizontal position of the needle tip of the probe 19A in the alignment chamber 13, and, the correction value is registered in the storage unit. Using the correction value, the alignment apparatus of this embodiment aligns the semiconductor wafer with the probe card 19. Here, FIGS. 6A to 6C schematically show the alignment process using the alignment apparatus shown in FIGS. 3A and 3B.

The probe correction card 33 derived from the probe card detecting apparatus 30 is transferred with the second card holder 33B into the alignment chamber 13 of the alignment apparatus via the wafer holder 15 (see FIGS. 3A and 3B), and is positioned and mounted on the positioning member 14B (see FIGS. 3A and 3B) waiting in the alignment chamber 13. Then, the moving body 14A lifts the probe correction card 33 together with the holding plate 15A from the supporting body 15B and stops at a focal length (alignment height) of the first and second cameras 14C₁ and 14C₂ of the alignment mechanism 14. In this case, the first and second cameras 14C₁ and 14C₂ operate and, at the same time, the moving body 14A moves in the horizontal direction, such that two targets 33A are detected as shown in FIGS. 6A to 6C. At this time, the horizontal position of the moving body 14 is registered as XY coordinates indicating the horizontal position of the targets 33A in the storage unit of the control device. If targets 33A of the probe correction card 33 are registered in the storage unit of the control device, the probe correction card 33 is unloaded from the alignment chamber 13 via the wafer holder 15.

Continuously, if the semiconductor wafer W is transferred into the alignment chamber 13 via the wafer holder 15 and is lifted together with the supporting plate 15A to the alignment height by the moving body 14A, as in the case with the probe correction card 33, and the electrode pad of the semiconductor wafer W is detected by the first and second cameras 14C₁ and 14C₂ as shown in FIG. 6A, the horizontal position of the moving body 14A at this time is registered as the XY coordinates indicating a horizontal position of the electrode pad with the storage unit of the control device. Then, as shown in FIG. 6C, the moving body 14A moves horizontally by the correction value obtained using the probe card detecting apparatus 30. The horizontal position of the semiconductor wafer W at this time becomes a position at which the electrode pad makes contact with the probe 19A of the probe card 19 within the inspection chamber 17. Through the sequence of these actions, the alignment of the semiconductor wafer W with the probe card 19 in the inspection chamber 17 will be completed. Thereafter, if the moving body 14A moves downward to convey the semiconductor wafer W onto the supporting body 15B of the wafer holder 15 (see FIGS. 3A and 3B), the semiconductor wafer W is transferred from the alignment chamber 13 to the inspection chamber 17 via the wafer holder 15.

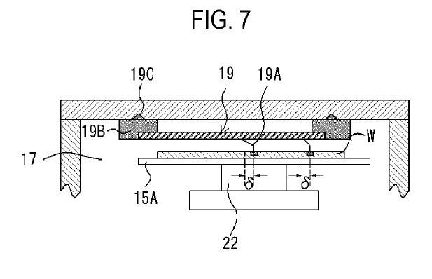

Since the inspection chamber 17 has the same XY coordinates that the alignment chamber 13 has, the semiconductor wafer W in the alignment chamber 13 is transferred, as it is, and conveyed onto the elevation body 22 within the inspection chamber 17. At this time, the plurality of recesses 15C₁ of the positioning member 15C of the wafer holder 15 are fitted with the plurality of protrusions 22B of the elevation body 22, so that the wafer holder 15 is positioned automatically within the inspection chamber 17, maintaining the alignment in the alignment chamber 13. Then, the elevation body 22 is elevated so that the semiconductor wafer W may electrically make contact with the probe card 19 reliably, as shown in FIG. 7. In this state, the electrical characteristics of the semiconductor wafer W are inspected. In addition, FIG. 7 schematically shows the main part of the inspection chamber shown in FIG. 4.

The semiconductor wafer W after inspection, is returned to the cassette through a path which is reverse to or different from the path leading to the inspection. Then, the above procedure is repeated at the next inspection

According to the embodiment as described above, the probe card detecting apparatus 30 includes a first step of obtaining a correction value δ necessary for the alignment of the semiconductor wafer W and the probe card 19 mounted on the probe detecting chamber 31 with the first and second cameras 32A and 32B of the first imaging device, using two probes 19A of the probe card 19 positioned and detachably mounted via the first card holder 19B and two targets 33A of the probe correction card 33 positioned and detachably mounted via the second card holder 33B in the probe detecting chamber 31, a second step of detecting two targets 33A by moving the probe correction card 33 held by the second card holder 33B via the moving body 14A in the alignment apparatus and using the first and second cameras 14C₁ and 14C₂ of the alignment mechanism 14, a third step of detecting two electrode pads of the semiconductor wafer W2 by moving the semiconductor wafer W via the moving body 14A of the alignment apparatus and using the first and second cameras 14C₁ and 14C₂ and a fourth step of performing a position alignment of the semiconductor wafer W with the probe card 19 mounted in the inspection chamber 17 by moving the semiconductor wafer W in accordance with the correction value via the moving body 14A. Therefore, in the inspection chamber 17 of the wafer inspecting apparatus, it is possible to align the semiconductor wafer W with the probe card 19 quickly and reliably without detecting the needle tip of the probe 19A of the probe card 19 or using a dummy wafer.

In addition, the first step includes a step of detecting the horizontal position of needle tips of two probes 19A of the probe card 19 mounted via the first card holder 19B in the probe detecting chamber 31 using the first and second cameras 32A and 32B, a step of detecting the horizontal position of two targets 33A of the probe correction card 33 mounted via the second card holder 33B in the probe detecting chamber 31 using the first and second cameras 32A and 32B, and a step of obtaining a difference between the horizontal position of needle tips of two probes 19A of the probe card 19 and the horizontal position of two targets 33A of the probe correction card 33 as a correction value δ. Therefore, it is possible to obtain the correction value used in the alignment apparatus easily.

According to the present disclosure in some embodiments, it is possible to provide a probe card detecting apparatus, a wafer position alignment apparatus and a wafer position alignment method through which the position alignment of a semiconductor wafer with a probe card may be performed quickly and reliably, without detecting the needle tip of the probe of the probe card in the inspection chamber of the wafer inspection apparatus, and without using a dummy wafer.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A probe card detecting apparatus, comprising:
a probe detecting chamber, which is configured to be positioned opposite an inspection chamber configured to inspect electrical characteristics of a semiconductor wafer, the probe detecting chamber including a supporting body configured to position and mount thereon a probe card detachably at a predetermined position;
a probe card positioned and mounted detachably via a first holder in the predetermined position of the supporting body;
a first imaging device provided movably in the probe detecting chamber to detect needle tips of at least two probes of the probe card;
a probe correction card positioned and mounted detachably, instead of the probe card, via a second holder in the predetermined position of the supporting body, the probe correction card having at least two targets corresponding to said at least two probes; and
a control device using the first imaging device in the probe detecting chamber to determine a difference between a horizontal position of needle tips of said at least two probes and a horizontal position of said at least two targets being detected as a correction value used for performing a position alignment of the at least two probes of the probe card in the inspection chamber with the at least two electrode pads of said semiconductor wafer.

2. The probe card detecting apparatus of claim 1, wherein both the first and second holder have at least three pins for positioning, and the supporting body has recesses for positioning the recesses corresponding to said at least three pins

3. The probe card detecting apparatus of claim 1, wherein the first imaging device captures an image of said probe or said target from below.

4. The probe card detecting apparatus of claim 1, wherein the probe card has a dedicated probe correction card.

5. A wafer position alignment apparatus, comprising:
a position alignment chamber;
a moving body movably provided in said position alignment chamber;
a second imaging device provided on said moving body; and
a control device configured to move the moving body which mounts thereon a second holder together with a probe correction card for which the correction value is obtained in a probe card detecting apparatus to detect at least two targets of said probe correction card with the use of the second imaging device and move the moving body which mounts thereon a semiconductor wafer to detect at least two electrode pads of said semiconductor wafer and, at the same time, said moving body being moved horizontally by the correction value from the position at which said electrode pads are detected.

6. The wafer position alignment apparatus of claim 5, wherein the probe card detecting apparatus comprises:
a probe detecting chamber, which is configured to be positioned opposite an inspection chamber configured to inspect electrical characteristics of a semiconductor wafer, the probe detecting chamber including a supporting body configured to position and mount thereon a probe card detachably at a predetermined position;
a probe card positioned and mounted detachably via a first holder in the predetermined position of the supporting body;
a first imaging device provided movably in the probe detecting chamber to detect needle tips of at least two probes of the probe card;
a probe correction card positioned and mounted detachably, instead of the probe card, via a second holder in the predetermined position of the supporting body, the probe correction card having at least two targets corresponding to said at least two probes; and
a control device using the first imaging device in the probe detecting chamber to determine a difference between a horizontal position of needle tips of said at least two probes and a horizontal position of said at least two targets being detected as a correction value used for performing a position alignment of the at least two probes of the probe card in the inspection chamber with the at least two electrode pads of said semiconductor wafer.

7. A wafer position alignment method, comprising:
finding a correction value needed for a position alignment of a semiconductor wafer with a probe card mounted in a probe detecting chamber, with the use of a first imaging device in a probe card detecting apparatus, using at least two probes of the probe card positioned and mounted detachably via a first holder in the probe detecting chamber and using at least two targets of a probe correction card positioned and mounted detachably via a second holder in said probe detecting chamber;
detecting said at least two targets using a second imaging device by moving said probe correction card held by the second holder via a moving body in a wafer position alignment apparatus;
detecting at least two electrode pads of the semiconductor wafer using the second imaging device by moving the semiconductor wafer via the moving body in the wafer position alignment apparatus; and
performing a position alignment with the probe card mounted in an inspection chamber by moving the semiconductor wafer via the moving body in accordance with the correction value.

8. The wafer position alignment method of claim 7, wherein the probe card detecting apparatus comprises:
a probe detecting chamber, which is configured to be positioned opposite an inspection chamber configured to inspect electrical characteristics of a semiconductor wafer, the probe detecting chamber including a supporting body configured to position and mount thereon a probe card detachably at a predetermined position;
a probe card positioned and mounted detachably via a first holder in the predetermined position of the supporting body;
a first imaging device provided movably in the probe detecting chamber to detect needle tips of at least two probes of the probe card;
a probe correction card positioned and mounted detachably, instead of the probe card, via a second holder in the predetermined position of the supporting body, the probe correction card having at least two targets corresponding to said at least two probes; and
a control device using the first imaging device in the probe detecting chamber to determine a difference between a horizontal position of needle tips of said at least two probes and a horizontal position of said at least two targets being detected as a correction value used for performing a position alignment of the at least two probes of the probe card in the inspection chamber with the at least two electrode pads of said semiconductor wafer.

9. The wafer position alignment method of claim 7, wherein the wafer position alignment apparatus comprises:
a position alignment chamber;
a moving body movably provided in said position alignment chamber;
a second imaging device provided on said moving body; and
a control device configured to move the moving body which mounts thereon a second holder together with a probe correction card for which the correction value is obtained in a probe card detecting apparatus to detect at least two targets of said probe correction card with the use of the second imaging device and move the moving body which mounts thereon a semiconductor wafer to detect at least two electrode pads of said semiconductor wafer and, at the same time, said moving body being moved horizontally by the correction value from the position at which said electrode pads are detected.

10. The wafer position alignment method of claim 7, wherein finding a correction value comprises:
detecting the horizontal position of needle tips of at least two probes of the probe card mounted via the first holder in the probe detecting chamber, with the use of the first imaging device;
detecting the horizontal position of at least two targets of the probe correction card mounted via the second holder in the probe detecting chamber, with the use of the first imaging device; and
obtaining a difference between the horizontal position of needle tips of at least two probes of the probe card and the horizontal position of at least two targets of the probe correction card as said correction value.
